(19) United States
(12) Patent Application Publication
(10) Pub. No.: US 2012/0292729 A1
(43) Pub. Date: Nov. 22, 2012

(54) Optoelectronic Devices Having Deep Level Defects and Associated Methods

(75) Inventor: Christopher Vineis, Watertown, MA (US)

(73) Assignee: SiOnyx, Inc., Beverly, MA (US)

(21) Appl. No.: 13/472,325

(22) Filed: May 15, 2012

Related U.S. Application Data
(60) Provisional application No. 61/487,166, filed on May 17, 2011.

(51) Int. Cl. H01L 31/0236; H01L 31/18

(52) U.S. Cl. 257/436; 438/71; 257/E31.13; 257/E31.004

(57) ABSTRACT

Semiconductor structures, devices, and methods that can exhibit various enhanced properties, such as, for example, enhanced light detection properties are provided. In one aspect, for example, an optoelectronic device can include a semiconductor material having an enhanced absorption region and a first defect in the enhanced absorption region, where the first defect is a deep-level defect generated by a first defect carrier type that is either a deep-level donor carrier type or a deep-level acceptor carrier type. The device can also include a second defect in the enhanced absorption region, where the second defect is either a shallow-level defect or a deep-level defect, and where the second defect is generated by a second defect carrier type that is opposite to the first defect carrier type. Furthermore, the enhanced absorption region has an external quantum efficiency of at least about 0.5% for electromagnetic radiation wavelengths greater than 1250 nm.

### PRIORITY DATA

This application claims the benefit of U.S. Provisional Patent Application Ser. No. 61/487,166, filed on May 17, 2011, which is incorporated herein by reference.

### BACKGROUND

Silicon is a very prevalent semiconductor material used in many electronic devices, and is also very widely used for optoelectronic devices such as optical detectors, image sensors and solar cells. The bandgap of silicon at room temperature is about 1.12 eV, and in general semiconductors do not absorb photons that have energies below their bandgap energy. However, there are many applications that require optical detection at lower energy levels than silicon's bandgap. Of particular interest, for example, are the energy levels 0.95 eV (1310 nm) and 0.8 eV (1550 nm). These applications are typically served by other semiconductors with smaller bandgaps, such as germanium, indium gallium arsenide, mercury cadmium telluride and the like.

### SUMMARY

The present disclosure provides semiconductor structures, devices, and methods that can exhibit various enhanced properties, such as, for example, enhanced light detection properties. In one aspect, for example, an optoelectronic device can include a semiconductor material having an enhanced absorption region and a first defect in the enhanced absorption region, where the first defect is a deep-level defect generated by a first defect carrier type that is either a deep-level donor carrier type or a deep-level acceptor carrier type. The device can also include a second defect in the enhanced absorption region, where the second defect is either a shallow-level defect or a deep-level defect, and where the second defect is generated by a second defect carrier type that is opposite to the first defect carrier type. Furthermore, the enhanced absorption region has an external quantum efficiency of at least about 0.5% for electromagnetic radiation wavelengths greater than 1250 nm.

In another aspect, a method of making an opto electronic device is provided. Such a method can include creating a first defect in a target region of a semiconductor material, where the first defect is a deep-level defect generated by a first defect carrier that is either a deep-level donor carrier type or a deep-level acceptor carrier type. The method can also include creating a second defect in at least a portion of the target region, where the second defect is either a shallow-level defect or a deep-level defect, and where the second defect is generated by a second defect carrier that is an opposite type to the first defect carrier to form an enhanced absorption region.

### BRIEF DESCRIPTION OF THE DRAWINGS

For a further understanding of the nature and advantage of the present disclosure, reference is being made to the following detailed description of embodiments and in connection with the accompanying drawings, in which:

FIG. 1 is an illustration of photon absorption in a semiconductor;

FIG. 2 is a graphical depiction of data showing external quantum efficiency in accordance with one embodiment of the present disclosure;

FIG. 3 is a graphical depiction of data showing external quantum efficiency in accordance with another embodiment of the present disclosure;

FIG. 4 is a graphical depiction of data showing external quantum efficiency in accordance with another embodiment of the present disclosure;

FIG. 5 is a cross-sectional view of a semiconductor structure in accordance with another embodiment of the present disclosure;

FIG. 6 is a cross-sectional view of a semiconductor structure in accordance with another embodiment of the present disclosure;

FIG. 7 is a cross-sectional view of a semiconductor structure in accordance with another embodiment of the present disclosure;

FIG. 8 is a cross-sectional view of a semiconductor structure in accordance with another embodiment of the present disclosure;

FIG. 9 is a cross-sectional view of a semiconductor structure in accordance with another embodiment of the present disclosure; and

FIG. 10 is a depiction of a method of making a semiconductor device in accordance with another aspect of the present disclosure.

### DETAILED DESCRIPTION

Before the present disclosure is described herein, it is to be understood that this disclosure is not limited to the particular structures, process steps, or materials disclosed herein, but is extended to equivalents thereof as would be recognized by those ordinarily skilled in the relevant arts. It should also be understood that terminology employed herein is used for the purpose of describing particular embodiments only and is not intended to be limiting.

### DEFINITIONS

The following terminology will be used in accordance with the definitions set forth below.

It should be noted that, as used in this specification and the appended claims, the singular forms “a,” and, “the” include plural referents unless the context clearly dictates otherwise. Thus, for example, reference to “a dopant” includes one or more of such dopants and reference to “the layer” includes reference to one or more of such layers.

As used herein, the terms “disordered surface” and “textured surface” can be used interchangeably, and refer to a surface having a topology with nano- to micron-sized surface variations. Although any texturing technique is considered to be within the present scope, in one aspect the texturing is formed by the irradiation of laser pulses. Furthermore, while the characteristics of a textured surface can be variable depending on the materials and techniques employed, in one aspect such a surface can be several hundred nanometers thick and made up of nanocrystallites (e.g. from about 10 to about 50 nanometers), nanopores, and the like. In another aspect, such a surface can include micron-sized structures (e.g. about 2 μm to about 60 μm). In yet another aspect, the surface can include nano-sized and/or micron-sized structures from about 5 nm and about 500 μm.

As used herein, the terms “surface modifying,” “surface modification,” and “texturing” can be used interchangeably, and refer to the altering of a surface of a semiconductor material using a texturing technique. In one specific aspect, surface modification can include processes using primarily laser radiation or laser radiation in combination with a dopant, whereby the laser radiation facilitates the incorporation of the dopant into a surface of the semiconductor material. Accordingly, in one aspect surface modification includes doping the material.

As used herein, the term “fluence” refers to the amount of energy from a single pulse of laser radiation that passes through a unit area. In other words, “fluence” can be described as the energy density of one laser pulse.

As used herein, the term “target region” refers to an area of a semiconductor material that is intended to be doped or surface modified using laser radiation. The target region of a semiconductor material can vary as the surface modifying process progresses. For example, after a first target region is doped or surface modified, a second target region may be selected on the same semiconductor material.

As used herein, the term “complex” refers to a group of two or more constituents, atoms, defects, or vacancies that are in close proximity or bonded together.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

The Disclosure

The present disclosure provides devices and structures, including associated methods, wherein the sub-bandgap quantum efficiency of a semiconductor material is increased. Various techniques of accomplishing such an increase are outlined further herein. It should be noted that, while portions of the discussion refer specifically to silicon semiconductor materials, the present scope should not be limited to such, and other semiconductor materials should be considered where applicable.

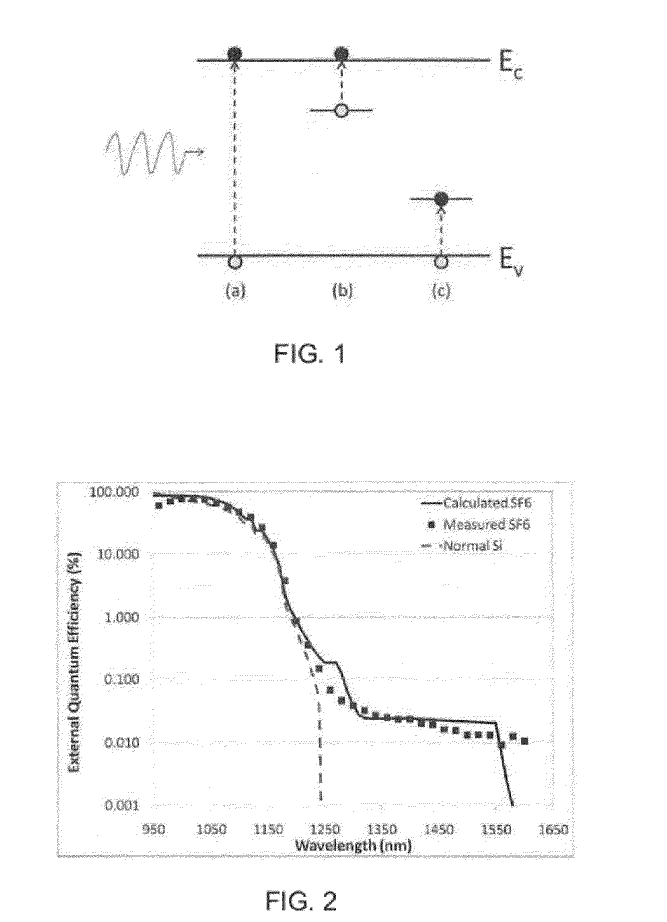

Various methods can be utilized to achieve sub-bandgap absorption in silicon. For example, photoconductive silicon can be extended out to nearly 0.18 eV (7 μm) by doping with deep-level donors, such as sulfur or selenium. Further improvements can be made by counter doping with a shallow acceptor. Absorptance above 90% out to at least 2.5 μm can also be achieved using femtosecond lasing of silicon in SF₆. Such absorption may be achieved by creating a deep-level defect in the bandgap of silicon that can be photoionized. Essentially, the deep-level defect can create a free (conduction) electron or (valence) hole by absorption of a photon. As one example of such deep-level defect absorption, FIG. 1 shows a schematic illustration of photon absorption in a semiconductor. In one case, a photon (a) undergoes a normal band-to-band absorption that occurs at energies at or above the bandgap of the material. In another case, a photon (b) undergoes a deep-level donor defect to conduction band absorption. In yet another case, a photon (c) undergoes a valence band to deep-level acceptor defect absorption. Note that Ec is the conduction band edge, Ev is the valence band edge, solid circles represent electrons, and open circles represent holes (absence of an electron). Many of these described methods, however, have various limitations such as, for example, low absorption coefficients that need very long device lengths for appreciable signal strength, and the need for large reverse biases to achieve sufficient responsivities.

The present disclosure provides devices, including associated methods, wherein the sub-bandgap quantum efficiency of a semiconductor material is increased by combining a deep-level defect of either a donor or an acceptor carrier type and either a shallow or a deep-level defect of the opposite character type. Thus, by introducing such donor and acceptor carrier type defects into the semiconductor material, an enhanced absorption region is formed and the external quantum efficiency of the semiconductor material is increased. Additionally, in a further aspect a textured region can be functionally associated with the enhanced absorption region to further increase the external quantum efficiency of the device. This device configuration can effectively increase the optical thickness of the layer (i.e. increase the apparent thickness of the layer to incoming wavelengths of electromagnetic radiation) without increasing the physical thickness, thus avoiding many of the device performance drawbacks associated with thicker devices.

As one example, FIG. 2 compares measured (solid squares) and calculated (solid and dashed lines) external quantum efficiency data for SF₆-lased silicon. This exemplary structure has sulfur deep donor level defects embedded in the lased silicon layer, which is approximately 300 nm thick. Calculations are performed using SCAPS, a software program that allows photoionization contributions from defect states in the bandgap. FIG. 2 shows that there is good agreement between the measured and calculated data. Also shown for comparison is a calculation for normal silicon (i.e. without the inclusion of sulfur), showing a typical absorption cutoff at ˜1200 nm. The inclusion of sulfur thus enables sub-bandgap quantum efficiency in silicon, beyond the typical wavelength cutoff of ˜1200 nm.

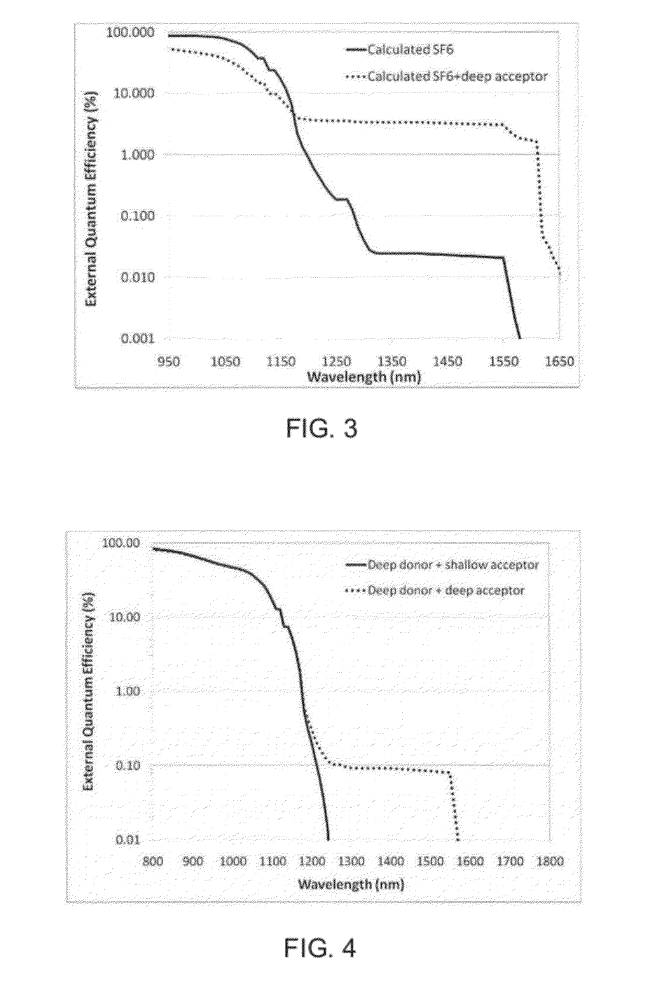

Although the inclusion of sulfur enables sub-bandgap quantum efficiency, such quantum efficiency is low (˜0.05%). Such a low value may not be useful for many devices where alternative semiconductor materials exist with better performance. In contrast, by introducing a deep acceptor the into the silicon material, sub-bandgap quantum efficiency can be dramatically improved. Such an improvement is calculated and shown in FIG. 3, where lased silicon doped with only sulfur (solid line) is compared to lased silicon simultaneously doped with sulfur and counter-doped with a deep-level acceptor (dotted line). The sub-bandgap quantum efficiency is about 100 times higher with the use of the deep acceptor co-dopant. The resulting efficiency values (>1%) are sufficiently high to make practically useful optoelectronic devices, such as detectors and image sensors, from silicon. The improved performance may be due to the presence of the co-dopant favorably changing the electron occupation statistics of the various deep levels, as well as the electron and hole recombination statistics. As such, a greater density of electron-hole pairs can be optically created in the layer, resulting in higher quantum efficiency. Optimum performance may be obtained when the concentration of all acceptor levels equals all donor levels. In this example, since sulfur is a double donor in silicon and the deep acceptor is modeled as a single level, optimum performance is given when the acceptor concentration is two times that of the sulfur concentration.

It should also be noted that such high quantum efficiencies are achieved in a thin silicon layer. The above calculations assume a textured silicon layer, in this case a lased textured region. This, along with the two dopants, is only 300 nm thick. Such high quantum efficiencies can be achieved in thin layers partially because of 1) the large photoionization cross-section of sulfur deep levels in silicon, and 2) the light-trapping effect of the textured silicon. Without such light trapping, the effective quantum efficiency can be ˜10 times lower, and an accordingly thicker silicon layer would be necessary to achieve the same level of absorption. The use of a thicker layer can have various drawbacks, including reduced detector speed, increased device cost, more difficult integration, etc. It should be noted, however, that the present scope is not limited to thin semiconductor materials, and that such materials of any thicknesses can be utilized.

It is also possible to achieve a similar effect using a shallow level acceptor, rather than a deep level acceptor. One potential issue to manage, however, is that the concentration of donor electrons should be equal or exceed the concentration of acceptor states. In some cases, if the number of acceptors exceeds the concentration of donors, the sub-bandgap quantum efficiency can be eliminated. This is shown by the solid line in FIG. 4, where the shallow level acceptor concentration is 5×10¹⁸/cm³, while the sulfur concentration is 2×10¹⁸/cm³. Note that sulfur is a double donor in silicon, so a sulfur concentration of 2×10¹⁸/cm³ yields 4×10¹⁸/cm³ electrons. In contrast, the use of a deep acceptor does not have such a steep dependence. As is shown by the dotted line in FIG. 4, the same concentration (5×10¹⁸/cm³) of a deep level acceptor is used, and although the efficiency is not as high as for the optimum case (i.e. acceptor concentration of 4×10¹⁸/cm³), it is still present. Thus, the use of a deep level acceptor rather than a shallow level acceptor increases the process window and eases manufacturing constraints. More generally this same concept could be applied to the use of a deep level acceptor and a shallow level donor, and it could also be applied to materials other than silicon.

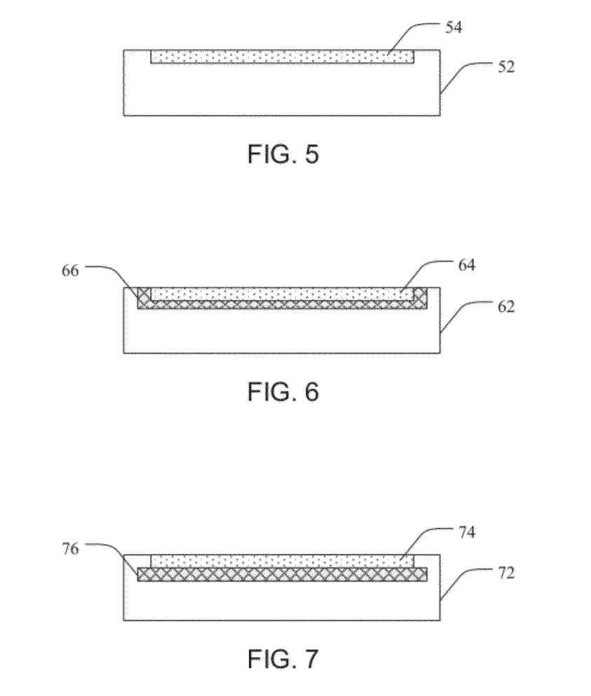

Various device configurations are contemplated, and any such conceivable configuration is considered to be within the present scope. In one aspect, as is shown in FIG. 5 for example, an optoelectronic device is provided. Such a device can include a semiconductor material 52 having an enhanced absorption region 54. The device includes a first defect in the enhanced absorption region, where the first defect is a deep-level defect generated by a first defect carrier type that is either a deep-level donor carrier type or a deep-level acceptor carrier type. The device also includes a second defect in the enhanced absorption region, where the second defect is either a shallow-level defect or a deep-level defect. Additionally, the second defect is generated by a second defect carrier type that is opposite to the first defect carrier type. Furthermore, the enhanced absorption region has an external quantum efficiency of at least about 0.5% for electromagnetic radiation wavelengths greater than 1250 nm. In another aspect, the enhanced absorption region has an external quantum efficiency of at least about 0.5% for electromagnetic radiation wavelengths of from about 1250 nm to about 7500 nm. In yet another aspect, the enhanced absorption region has an external quantum efficiency of at least about 0.5% for electromagnetic radiation wavelengths of from about 1250 nm to about 3000 nm. In a further aspect, the enhanced absorption region has an external quantum efficiency of at least about 0.5% for electromagnetic radiation wavelengths of from about 1250 nm to about 1600 nm. In another aspect, the enhanced absorption region has an external quantum efficiency of at least 1% for electromagnetic radiation wavelengths greater than 1250 nm. In yet another aspect, the enhanced absorption region has an external quantum efficiency of at least 5% for electromagnetic radiation wavelengths greater than 1250 nm. In a further aspect, the enhanced absorption region has an external quantum efficiency of at least 10% for electromagnetic radiation wavelengths greater than 1250 nm. It should be noted that, in some aspects, the enhanced absorption region also includes the textured region, and thus the values for external quantum efficiency may also include effects that can be attributed at least partially to the textured region.

The external quantum efficiencies can also be presented as a relative increase of a semiconductor material having an enhanced absorption region as compared to an equivalent semiconductor material lacking an enhanced absorption region.

A variety of semiconductor materials are contemplated for use with the devices and methods according to aspects of the present disclosure. Non-limiting examples of such semiconductor materials can include group IV materials, compounds and alloys comprised of materials from groups II and VI, compounds and alloys comprised of materials from groups III and V, and combinations thereof. More specifically, exemplary group IV materials can include silicon, carbon (e.g. diamond), germanium, and combinations thereof. Various exemplary combinations of group IV materials can include silicon carbide (SiC) and silicon germanium (SiGe). In one specific aspect, the semiconductor material can be or include silicon. Exemplary silicon materials can include amorphous silicon (a-Si), microcrystalline silicon, multicrystalline silicon, and monocrystalline silicon, as well as other crystal types. In another aspect, the semiconductor material can include at least one of silicon, carbon, germanium, aluminum nitride, gallium nitride, indium gallium arsenide, aluminum gallium arsenide, and combinations thereof.

Exemplary combinations of group II-VI materials can include cadmium selenide (CdSe), cadmium sulfide (CdS), cadmium telluride (CdTe), zinc oxide (ZnO), zinc selenide (ZnSe), zinc sulfide (ZnS), zinc telluride (ZnTe), cadmium zinc telluride (CdZnTe, CZT), mercury cadmium telluride (HgCdTe), mercury zinc telluride (HgZnTe), mercury zinc selenide (HgZnSe), and combinations thereof.

Exemplary combinations of group III-V materials can include aluminum antimonide (AlSb), aluminum arsenide (AlAs), aluminum nitride (AlN), aluminum phosphide (AlP), boron nitride (BN), boron phosphide (BP), boron arsenide (BAs), gallium antimonide (GaSb), gallium arsenide (GaAs), gallium nitride (GaN), gallium phosphide (GaP), indium antimonide (InSb), indium arsenide (InAs), indium nitride (InN), indium phosphide (InP), aluminum gallium arsenide (AlGaAs, AlₓGa₁₋ₓAs), indium gallium arsenide (InGaAs, InₓGa₁₋ₓAs), indium gallium phosphide (InGaP), aluminum indium arsenide (AlInAs), aluminum indium antimonide (AlInSb), gallium arsenide nitride (GaAsN), gallium arsenide phosphide (GaAsP), aluminum gallium nitride (AlGaN), aluminum gallium phosphide (AlGaP), indium gallium nitride (InGaN), indium arsenide antimonide (InAsSb), indium gallium antimonide (InGaSb), aluminum gallium indium phosphide (AlGaInP), aluminum gallium arsenide phosphide (AlGaAsP), indium gallium arsenide phosphide (InGaAsP), aluminum indium arsenide phosphide (AIInAsP), aluminum gallium arsenide nitride (AlGaAsN), indium gallium arsenide nitride (InGaAsN), indium aluminum arsenide nitride (InAlAsN), gallium arsenide antimonide nitride (GaAsSbN), gallium indium nitride arsenide antimonide (GaInNAsSb), gallium indium arsenide antimonide phosphide (GaInAsSbP), and combinations thereof.

The semiconductor material can be of any thickness that allows the desired property or functionality of the semiconductor device, and thus any such thickness of semiconductor material is considered to be within the present scope. The textured region can increase the efficiency of the device such that, in some aspects, the semiconductor material can be thinner than has previously been possible. Decreasing the thickness reduces the amount of semiconductor material used to make such a device. It is noted, however, that the present disclosure relates to any thickness of semiconductor material. In one aspect, for example, a semiconductor material such as the semiconductor layer has a thickness of from about 500 nm to about 50 μm. In another aspect, the semiconductor material has a thickness of less than or equal to about 500 μm. In yet another aspect, the semiconductor material has a thickness of from about 1 μm to about 10 μm. In a further aspect, the semiconductor material can have a thickness of from about 5 μm to about 750 μm. In yet a further aspect, the semiconductor material can have a thickness of from about 5 μm to about 100 μm. In another aspect, the semiconductor material can have a thickness that is greater than about 750 μm.

Additionally, various configurations of semiconductor materials are contemplated, and any such material configurations that can be incorporated into a semiconductor device are considered to be within the present scope. In one aspect, for example, the semiconductor material can include monocrystalline materials. In another aspect, the semiconductor material can include multicrystalline materials. In yet another aspect, the semiconductor material can include microcrystalline materials. It is also contemplated that the semiconductor material can include amorphous materials.

The semiconductor material can be coupled to a support substrate to facilitate handling of the device. The support substrate can be of any size, shape, and material capable of supporting the semiconductor material and associated components during manufacture and/or use. The support substrate can be made from various materials, including the semiconductor materials described above, as well as non-semiconductor materials. Non-limiting examples of such materials can include metals, polymeric materials, ceramics, glass, and the like.

As has been described, the enhanced absorption region includes a first deep-level defect in combination with either a second defect that is either a shallow-level defect or a deep-level defect. Additionally, the carrier type of the second defect is opposite to the first defect carrier type. For example, if the first defect is generated by a donor carrier type, the second defect is generated by an acceptor carrier type, and vice versa. Accordingly, in one aspect, the first defect is a deep-level defect generated by a deep-level donor carrier type and the second defect is a deep-level defect generated by a deep-level acceptor carrier type. In another aspect, the first defect is a deep-level defect generated by a deep-level acceptor carrier type and the second defect is a shallow-level defect generated by a shallow-level donor carrier type. In yet another aspect, the first defect is a deep-level defect generated by a deep-level donor carrier type and the second defect is a shallow-level defect generated by a shallow-level acceptor carrier type.

Various deep-level defects are contemplated, and any technique for generating such defects is considered to be within the present scope. In one aspect, a deep-level defect is greater than or equal to 50 mV from a band edge of the semiconductor material. In another aspect, the deep-level defect is greater than or equal to 100 mV from a band edge of the semiconductor material. Deep-level defects can include dopant species, as well as native defects introduced into the semiconductor material during formation of the semiconductor material or at some point thereafter. As has been described, in one aspect a deep-level defect can be a deep-level donor. Non-limiting examples of deep-level donors include S, Se, Te, Ti, Mo, Sn, Cr, W, K, a native defect, a complex between a native defect and oxygen, a complex between a native defect and a metal, and the like, including combinations thereof. Non-limiting examples of native defects include vacancies, divacancies, interstitials, and the like, including combinations thereof. In one aspect, the deep-level donor can include S, Se, Te, and combinations thereof.

In another aspect, a deep-level defect can be a deep-level acceptor. Non-limiting examples of deep-level acceptors include Pd, Ni, Cu, Cd, Zn, Co, In, a native defect, a complex between a native defect and oxygen, a complex between a native defect and a metal, and the like, including combinations thereof. As has been stated, non-limiting examples of native defects include vacancies, divacancies, interstitials, and the like, including combinations thereof. In one aspect, the deep-level acceptor can include Pd, Ni, Cu, Cd, Zn, Co, and combinations thereof.

Various shallow-level defects are contemplated, and any technique for generating such defects is considered to be within the present scope. In one aspect, a shallow-level defect is less than 50 mV from a band edge of the semiconductor material. Shallow-level defects can include dopant species, as well as native defects introduced into the semiconductor material during formation of the semiconductor material or at some point thereafter. As has been described, in one aspect a shallow-level defect can be a shallow-level acceptor. Non-limiting examples of shallow-level acceptors include B, Al, Ga, and the like, including combinations thereof. In another aspect, a shallow-level defect can be a shallow-level donor. Non-limiting examples of shallow-level donors include P, As, Sb, Li, Bi, and the like, including combinations thereof. In one specific aspect, the shallow-level donor includes P, As, and combinations thereof.

The various defects described can be introduced into the semiconductor material to form the enhanced absorption region via a various techniques. In one aspect, for example, a defect can be the result of doping a donor carrier type or an acceptor carrier type into the semiconductor material. One or both of the carrier types can be doped, and can be for shallow-level and/or deep-level defects. Doping can occur during formation of the semiconductor material or after the semiconductor material has been formed. Doping can be accomplished by any known method, including ion implantation, laser doping, diffusion doping, and the like. Additionally, for those aspects including a textured region, doping of one or more species can be accomplished via the texturing procedure. For example, one or more dopant species can be introduced into the enhanced absorption region during laser texturing. Additionally, native defects can be formed during the original crystal growth of the semiconductor material, or by post processing such as through damage created by ion implantation.

The enhanced absorption region can generally be made much thinner than has previously been possible. This does not preclude the use of the present techniques with materials of any thickness. In one aspect, however, the enhanced absorption region is from about 0.01 μm to about 5 μm thick. In another aspect, the enhanced absorption region is from about 0.01 μm to about 1 μm thick. In yet another aspect, the enhanced absorption region is from about 0.01 μm to about 0.5 μm thick.

As has been described, a textured region can be associated with the enhanced absorption region. The textured region can be a component of the enhanced absorption region or it can be distinct therefrom. The textured region can impart various beneficial effects to the enhanced absorption region, including, without limitation, increased light trapping and light absorption.

Turning to FIG. 6, an optoelectronic device is provided having a semiconductor material 62 and an enhanced absorption region 64 as has been described in FIG. 5. The device further includes a textured region 66 associated with the enhanced absorption region. With respect to FIG. 6, the textured region is part of the enhanced absorption region. In some aspects, the enhanced absorption region can be only partially textured, while in other aspects, the enhanced absorption region can be completely textured. Additionally, the textured region can extend beyond the enhanced absorption region, as is shown in FIG. 6, or the textured region can be merely a portion of the enhanced absorption region. In one aspect, the enhanced absorption region and the textured region can be formed at least partially simultaneously.

FIG. 7 shows one aspect having a semiconductor material 72, an enhanced absorption region 74 as has been described in FIG. 5, and a textured region 76 that is at least partially separate from the enhanced absorption region. The textured region and the absorption region can be adjacent to one another, can be separated by a portion of the semiconductor material or some other material, or there can be some overlap between the regions. In one aspect, the enhanced absorption region is formed at least partially on top of the textured region. Thus, according to FIG. 7, electromagnetic radiation entering the device at the enhanced absorption region will pass there through before striking the textured region.

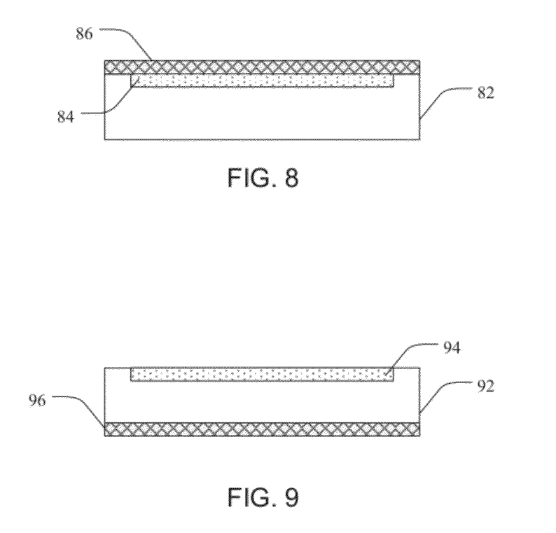

FIG. 8 shows one aspect having a semiconductor material 82, an enhanced absorption region 84 as has been described in FIG. 5, and a textured region 86 that is at least partially separate from the enhanced absorption region. The textured region and the absorption region can be adjacent to one another, can be separated by a portion of the semiconductor material or some other material, or there can be some overlap between the regions. In one aspect, the textured region is formed at least partially on top of the enhanced absorption region. Thus, according to FIG. 8, electromagnetic radiation entering the device at the textured region will pass there through before striking the enhanced absorption region.

FIG. 9 shows one aspect having a semiconductor material 92, an enhanced absorption region 94 as has been described in FIG. 5, and a textured region 96 that is distinct from the enhanced absorption region. In this case, the textured region is formed on the semiconductor material at a surface that is opposite the enhanced absorption region. Thus, according to FIG. 9, electromagnetic radiation entering the device at the enhanced absorption region will pass through the semiconductor material before striking the textured region.

The textured region can be formed to have a variety of physical configurations depending on the desired characteristics of the device. For example, the textured can be of various thicknesses. In one aspect, for example, the textured region has a thickness of from about 0.01 μm to about 100 μm. In another aspect, the textured region has a thickness of from about 0.01 μm to about 15 μm. In yet another aspect, the textured region has a thickness of from about 0.01 μm to about 2 μm. In a further aspect, the textured region has a thickness of from about 0.01 μm to about 1 μm.

The textured region can function to diffuse electromagnetic radiation, to redirect electromagnetic radiation, and/or to absorb electromagnetic radiation, thus increasing the quantum efficiency of the device. The textured region can include surface features to further increase the effective absorption length of the device. Non-limiting examples of shapes and configurations of surface features include cones, pillars, pyramids, microlenses, quantum dots, inverted features, gratings, protrusions, sphere-like structures, and the like, including combinations thereof. Additionally, surface features can be micron-sized, nano-sized, or a combination thereof. For example, cones, pyramids, protrusions, and the like can have an average height within this range. In one aspect, the average height would be from the base of the feature to the distal tip of the feature. In another aspect, the average height would be from the surface plane upon which the feature was created to the distal tips of the feature. In one specific aspect, a feature (e.g. a cone) can have a height of from about 50 nm to about 2 μm. As another example, quantum dots, microlenses, and the like can have an average diameter within the micron-sized and/or nano-sized range.

In addition to or instead of surface features, the textured region can include a substantially conformal textured layer. Such a textured layer can have an average thickness of from about 1 nm to about 5 μm. In those aspects where the textured region includes surface features, the conformal textured layer can have a varying thickness relative to the location on the surface features upon which is deposited. In the case of cones, for example, the conformal textured layer can become thinner toward the tips of the cones. Such a conformal layer can include various materials, including, without limitation, SiO₂, Si₃N₄, amorphous silicon, polysilicon, a metal or metals, and the like, including combinations thereof. The conformal textured layer can also be one or more layers of the same or different materials, and can be formed during the creation of surface features or in a separate process.

Textured regions according to aspects of the present disclosure can allow a photosensitive device to experience multiple passes of incident electromagnetic radiation within the device, particularly at longer wavelengths (i.e. infrared). Such internal reflection increases the effective absorption length to be greater than the thickness of the semiconductor layer. This increase in absorption length increases the quantum efficiency of the device.

The materials used for making the textured region can vary depending on the design and the desired characteristics of the device. As such, any material that can be utilized in the construction of a textured region is considered to be within the present scope. In one aspect, for example, the texture region can be a textured portion of a specific material, such as a portion of the semiconductor material. In another aspect, the textured region can be formed from a material that is deposited onto the semiconductor material, or the textured layer itself can be deposited. Such materials can include, for example, a semiconductor material. In one specific example, the deposited material can include a silicon material. In another specific example, the deposited material can be polysilicon.

The texturing process can texture the entire substrate to be processed or only a portion of the substrate. In one aspect, for example, a substrate such as the semiconductor material can be textured and patterned by an appropriate technique over an entire surface to form the textured region. In another aspect, a substrate such as the semiconductor material can be textured and patterned across only a portion of a surface by using a selective etching technique, such as a mask, photolithography, and an etch or a laser process to define a specific structure or pattern.

The textured region can be formed by various techniques, including plasma etching, reactive ion etching, porous silicon etching, lasing, chemical etching (e.g. anisotropic etching, isotropic etching), nanoimprinting, material deposition, selective epitaxial growth, and the like.

One effective method of producing a textured region is through laser processing. Such laser processing allows discrete target areas of a substrate to be textured, as well as entire surfaces. A variety of techniques of laser processing to form a textured region are contemplated, and any technique capable of forming such a region should be considered to be within the present scope. Laser treatment or processing can allow, among other things, enhanced absorption properties and thus increased external quantum efficiency.

In one aspect, for example, a target region of the substrate to be textured can be irradiated with laser radiation to form a textured region. Examples of such processing have been described in further detail in U.S. Pat. Nos. 7,057,256, 7,354,792 and 7,442,629, which are incorporated herein by reference in their entireties. Briefly, a surface of a substrate material is irradiated with laser radiation to form a textured or surface modified region. Such laser processing can occur with or without a dopant material. Such dopant materials can be used to form the deep- and/or shallow-level defects described herein, or they can be used to dope the textured region in addition to such defects. In those aspects whereby a dopant is used, the laser can be passed through a dopant carrier and onto the substrate surface. In this way, dopant from the dopant carrier is introduced into the target region of the substrate material. Such a region incorporated into a substrate material can have various benefits in accordance with aspects of the present disclosure. Various dopant materials are known in the art, and are discussed in more detail herein. Accordingly, the surface of the substrate at the target region is thus chemically and/or structurally altered by the laser treatment, which may, in some aspects, result in the formation of surface features appearing as structures or patterned areas on the surface and, if a dopant is used, the incorporation of such dopants into the substrate material.

The type of laser radiation used to surface modify a material can vary depending on the material and the intended modification. Any laser radiation known in the art can be used with the devices and methods of the present disclosure. There are a number of laser characteristics, however, that can affect the surface modification process and/or the resulting product including, but not limited to, the wavelength of the laser radiation, pulse width, pulse fluence, pulse frequency, polarization, laser propagation direction relative to the semiconductor material, etc. In one aspect, a laser can be configured to provide pulsatile lasing of a material. A short-pulsed laser is one capable of producing femtosecond, picosecond, and/or nanosecond pulse durations. Laser pulses can have a central wavelength in a range of about from about 10 nm to about 8 μm, and more specifically from about 200 nm to about 1200 nm. The pulse duration of the laser radiation can be in a range of from about one femtosecond to about hundreds of nanoseconds. In one aspect, laser pulse widths can be in the range of from about 1 femtosecond to about 900 picoseconds. In one aspect, laser pulse widths can be in the range of from about 50 femtosecond to about 50 picoseconds. In another aspect, laser pulse widths are in the range of from about 50 to 500 femtoseconds.

The number of laser pulses irradiating a target region can be in a range of from about 1 to about 2000. In one aspect, the number of laser pulses irradiating a target region can be from about 2 to about 1000. Further, the repetition rate or frequency of the pulses can be selected to be in a range of from about 10 Hz to about 10 μHz, or in a range of from about 1 kHz to about 1 MHz, or in a range from about 10 Hz to about 1 kHz. Moreover, the fluence of each laser pulse can be in a range of from about 1 kJ/m² to about 20 kJ/m², or in a range of from about 3 kJ/m² to about 8 kJ/m².

As a general matter, a variety of dopant materials are contemplated for both the formation of doped regions in the semiconductor material and for doping of the textured region, and any dopant that can be used in such processes to modify a material is considered to be within the present scope. It should be noted that the particular dopant utilized can vary depending on the material being doped, as well as the intended use of the resulting material.

A dopant can be either a charge donating or a charge accepting dopant species. More specifically, an electron donating or a hole donating species can cause a region to become more positive or negative in polarity as compared to the substrate upon which the rests. In one aspect, for example, the doped region can be p-doped. In another aspect the doped region can be n-doped.

In one aspect, non-limiting examples of dopant materials can include S, F, B, P, N, As, Se, Te, Ge, Ar, Ga, In, Sb, and combinations thereof. It should be noted that the scope of dopant materials should include, not only the dopant materials themselves, but also materials in forms that deliver such dopants (i.e. dopant carriers). For example, S dopant materials includes not only S, but also any material capable being used to dope S into the target region, such as, for example, H₂S, SF₆, SO₂, and the like, including combinations thereof. In one specific aspect, the dopant can be S. Sulfur can be present at an ion dosage level of from about 5×10¹⁴ to about 3×10²⁰ ions/cm². Non-limiting examples of fluorine-containing compounds can include ClF₃, PF₅, F₂SF₆, BF₃, GeF₄, WF₆, SiF₄, HF, CF₄, CHF₃, CH₂F₂, CH₃F, C₂F₆, C₂HF₅, C₃F₈, C₄F₈, NF₃, and the like, including combinations thereof. Non-limiting examples of boron-containing compounds can include B(CH₃)₃, BF₃, BCl₃, BN, C₂B₁₀H₁₂, borosilica, B₂H₆, and the like, including combinations thereof. Non-limiting examples of phosphorous-containing compounds can include PF₅, PH₃, POCl₃, P₂O₅, and the like, including combinations thereof. Non-limiting examples of chlorine-containing compounds can include Cl₂, SiH₂Cl₂, HCl, SiCl₄, and the like, including combinations thereof. Dopants can also include arsenic-containing compounds such as AsH₃ and the like, as well as antimony-containing compounds. Additionally, dopant materials can include mixtures or combinations across dopant groups, i.e. a sulfur-containing compound mixed with a chlorine-containing compound. In one aspect, the dopant material can have a density that is greater than air. In one specific aspect, the dopant material can include Se, H₂S, SF₆, or mixtures thereof. In yet another specific aspect, the dopant can be SF₆ and can have a predetermined concentration range of about 5.0×10⁻⁸ mol/cm³ to about 5.0×10⁻⁴ mol/cm³. As one non-limiting example, SF₆ gas is a good carrier for the incorporation of sulfur into a substrate via a laser process without significant adverse effects on the material. Additionally, it is noted that dopants can also be liquid solutions of n-type or p-type dopant materials dissolved in a solution such as water, alcohol, or an acid or basic solution. Dopants can also be solid materials applied as a powder or as a suspension dried onto the wafer.

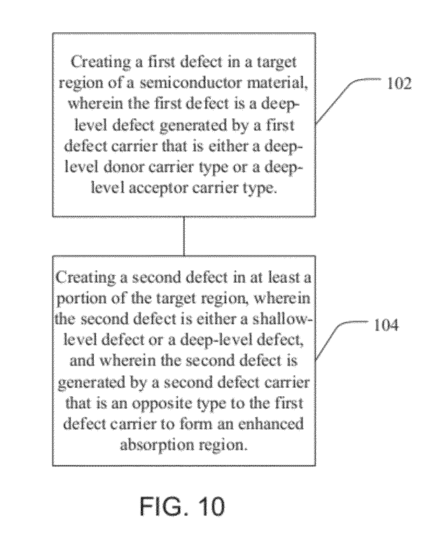

In another aspect, a method of making an optoelectronic device is provided. As is shown in FIG. 10, such a method can include creating a first defect in a target region of a semiconductor material, wherein the first defect is a deep-level defect generated by a first defect carrier that is either a deep-level donor carrier type or a deep-level acceptor carrier type 102. The method also includes creating a second defect in at least a portion of the target region, wherein the second defect is either a shallow-level defect or a deep-level defect, and wherein the second defect is generated by a second defect carrier that is an opposite type to the first defect carrier to form an enhanced absorption region 104. In one specific aspect, creating at least one of the first defect or the second defect is by doping. As has been described, doping can be by a technique such as, without limitation, ion implantation, epitaxial deposition, laser doping, diffusion doping, in situ doping, and the like, including combinations thereof. In yet another aspect, the method can further include forming a textured region in or on the semiconductor material positioned to interact with electromagnetic radiation that is functionally coupled to the enhanced absorption region.

Of course, it is to be understood that the above-described arrangements are only illustrative of the application of the principles of the present disclosure. Numerous modifications and alternative arrangements may be devised by those skilled in the art without departing from the spirit and scope of the present disclosure and the appended claims are intended to cover such modifications and arrangements. Thus, while the present disclosure has been described above with particularity and detail in connection with what is presently deemed to be the most practical embodiments of the disclosure, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. An optoelectronic device, comprising:
a semiconductor material having an enhanced absorption region;
a first defect in the enhanced absorption region, wherein the first defect is a deep-level defect generated by a first defect carrier type that is either a donor carrier type or an acceptor carrier type; and
a second defect in the enhanced absorption region, wherein the second defect is either a shallow-level defect or a deep-level defect, wherein the second defect is generated by a second defect carrier type that is either a donor carrier type or an acceptor carrier type with the proviso that the second defect carrier type is an opposite carrier type as the first defect carrier type,
wherein the enhanced absorption region has an external quantum efficiency of at least about 0.5% for electromagnetic radiation wavelengths greater than 1250 nm.

2. The device of claim 1, wherein the deep-level defect is greater than or equal to 50 mV from a band edge of the semiconductor material.

3. The device of claim 1, wherein the deep-level defect is greater than or equal to 100 mV from a band edge of the semiconductor material.

4. The device of claim 1, wherein the second defect is a shallow level defect and is less than 50 mV from a band edge of the semiconductor material.

5. The device of claim 1, wherein the deep-level donor carrier type includes a member selected from the group consisting of S, Se, Te, Ti, Mo, Sn, Cr, W, K, a native defect, a complex between a native defect and oxygen, a complex between a native defect and a metal, and combinations thereof.

6. The device of claim 1, wherein the deep-level donor carrier type includes a member selected from the group consisting of S, Se, Te, and combinations thereof.

7. The device of claim 1, wherein the deep-level acceptor carrier type includes a member selected from the group consisting of Pd, Ni, Cu, Cd, Zn, Co, In, a native defect, a complex between a native defect and oxygen, a complex between a native defect and a metal, and combinations thereof.

8. The device of claim 1, wherein the deep-level acceptor carrier type includes a member selected from the group consisting of Pd, Ni, Cu, Cd, Zn, Co, and combinations thereof.

9. The device of claim 1, wherein the first defect is generated by a donor carrier type and the second defect is a shallow-level defect generated by an acceptor carrier type.

10. The device of claim 9, wherein the acceptor carrier type includes a member selected from the group consisting of B, Al, Ga, and combinations thereof.

11. The device of claim 1, wherein the first defect is generated by a donor carrier type and the second defect is a deep-level defect generated by an acceptor carrier type.

12. The device of claim 1, wherein the first defect is generated by an acceptor carrier type and the second defect is a shallow-level defect generated by a donor carrier type.

13. The device of claim 12, wherein the donor carrier type includes a member selected from the group consisting of P, As, Sb, Li, Bi, and combinations thereof.

14. The device of claim 12, wherein the donor carrier type includes a member selected from the group consisting of P, As, and combinations thereof.

15. The device of claim 1, wherein enhanced absorption region is from about 0.01 μm to about 5 μm thick.

16. The device of claim 1, wherein the enhanced absorption region is from about 0.01 μm to about 1 μm thick.

17. The device of claim 1, wherein the enhanced absorption region is from about 0.01 μm to about 0.5 μm thick.

18. The device of claim 1, wherein the enhanced absorption region has an external quantum efficiency of at least 1% for electromagnetic radiation wavelengths greater than 1250 nm.

19. The device of claim 1, wherein the enhanced absorption region has an external quantum efficiency of at least 5% for electromagnetic radiation wavelengths greater than 1250 nm.

20. The device of claim 1, wherein the enhanced absorption region has an external quantum efficiency of at least 10% for electromagnetic radiation wavelengths greater than 1250 nm.

21. The device of claim 1, wherein the semiconductor material is silicon.

22. The device of claim 1, further comprising a textured region functionally coupled to the enhanced absorption region.

23. The device of claim 22, wherein the textured region is distinct from the enhanced absorption region.

24. The device of claim 22, wherein the enhanced absorption region includes the textured region.

25. The device of claim 22, wherein the textured region is a laser textured region.

26. A method of making an optoelectronic device, comprising:
creating a first defect in a target region of a semiconductor material, wherein the first defect is a deep-level defect generated by a first defect carrier type that is either a donor carrier type or an acceptor carrier type; and
creating a second defect in at least a portion of the target region, wherein the second defect is either a shallow-level defect or a deep-level defect, and wherein the second defect is generated by a second defect carrier type that is either a donor carrier type or an acceptor carrier type with the proviso that the second defect carrier type is of an opposite carrier type as the first defect carrier type, thus forming an enhanced absorption region, wherein the enhanced absorption region has an external quantum efficiency of at least about 0.5% for electromagnetic radiation wavelengths greater than 1250 nm.

27. The method of claim 26, wherein creating at least one of the first defect or the second defect is by doping.

28. The method of claim 27, wherein the defect doping is by a technique selected from the group consisting of ion implantation, epitaxial deposition, laser doping, diffusion doping, in situ doping, and combinations thereof.

29. The method of claim 26, further comprising forming a textured region in or on the semiconductor material positioned to interact with electromagnetic radiation that is functionally coupled to the enhanced absorption region.

30. The method of claim 29, wherein the textured region is formed by laser texturing using a pulsed laser with pulse durations of from about 1 femtosecond to about 900 picoseconds.

31. The method of claim 29, wherein the textured region is formed by laser texturing using a pulsed laser with pulse durations of from about 50 femtoseconds to about 50 picoseconds.

32. The method of claim 26, wherein at least one of the first defect carrier type or the second defect carrier type is doped using the pulsed laser.

33. The method of claim 26, wherein the enhanced absorption region is formed to a thickness of from about 0.01 μm to about 5 μm.

34. The method of claim 26, wherein the enhanced absorption region is formed to a thickness of from about 0.01 μm to about 1 μm.

35. The method of claim 26, wherein the enhanced absorption region is formed to a thickness of from about 0.01 μm to about 0.5 μm.
